(19) United States
(12) Patent Application Publication
(10) Pub. No.: US 2008/0098269 A1
(43) Pub. Date: Apr. 24, 2008

(54) Mechanism for concurrent testing of multiple embedded arrays

(76) Inventors: Dilip K. Bhavsar, Shrewsbury, MA (US); Shweta V. Kabadi, Brookline, MA (US)

Correspondence Address: INTEL/BLAKELY, 1279 OAKMEAD PARKWAY, SUNNYVALE, CA, 94085-4040, US

(21) Appl. No.: 11/540,885

(22) Filed: Sep. 29, 2006

(51) Int. Cl. G01R 31/28

(52) U.S. Cl. 714/733

(57) ABSTRACT

In one embodiment, an apparatus and method for concurrent testing of multiple embedded arrays is disclosed. In one embodiment, the apparatus comprises a built-in self test (BIST) engine coupled to a plurality of arrays having different sizes to generate test packets targeted to an array with the most entries among the plurality of arrays, a plurality of address space control logic each associated with an array of the plurality of arrays, the address space control logic to adjust a broadcast address of the test packets to match an address space of its associated array, and an array width independent concurrent response evaluator (AWIC-RE) coupled to the plurality of arrays. In addition, the AWIC-RE includes a plurality of response collectors each associated with an array of the plurality of arrays, the response collector to collect test data from its associated array and serially shift the test data out, and a response evaluator to receive the test data response streams from the plurality of response collectors and to compress the serial response streams after each read. Other embodiments are also described.

### FIELD OF THE INVENTION

The embodiments of the invention relate generally to the field of semiconductor fabrication and, more specifically, relate to a mechanism for concurrent testing of multiple embedded arrays in a microprocessor.

### BACKGROUND

Every microprocessor includes many arrays of different types and sizes, including random access memory (RAM), register files, content addressable memory (CAM), queues (such as FIFO queues), and so on. These arrays are all tested as part of the processor fabrication process. Typically, test engines are utilized on the processor to test the arrays. In some cases, a test engine may be implemented for each of the arrays, which can take up a large amount of area on the chip. In other cases, a central test engine may be utilized, which may be shared for testing many arrays. The sharing reduces the hardware costs, but unfortunately requires that the arrays are tested sequentially one at a time. Each time an array is tested, the engine is programmed specifically to generate test procedure specific to the array's address space and data width. Then, test responses are brought back to the central engine for comparison and pass/fail status evaluation.

The sequential testing and the repeated programming impact test time and test cost. This cost particularity becomes excessive when arrays require testing with a large number of test algorithms in order to stream the manufacturing process. Furthermore, because of the repetitive programming required, this method is not easily extended to in-field applications, such as power on self test or on demand periodic self-test.

It would be beneficial to implement a testing mechanism that addresses the above problems in a time and cost effective manner.

### BRIEF DESCRIPTION OF THE DRAWINGS

The invention will be understood more fully from the detailed description given below and from the accompanying drawings of various embodiments of the invention. The drawings, however, should not be taken to limit the invention to the specific embodiments, but are for explanation and understanding only.

FIG. 1 illustrates a block diagram of one embodiment of a concurrent array test system;

FIG. 2 illustrates a block diagram of one embodiment of address space control logic;

FIG. 3 is a flow diagram of a method of one embodiment of the invention; and

FIG. 4 illustrates a block diagram of one embodiment of a computer system.

### DETAILED DESCRIPTION

A method and apparatus for a mechanism for concurrent testing of multiple embedded arrays are described. In the following detailed description of the present invention, numerous specific details are set forth in order to provide a thorough understanding of the present invention. However, it will be apparent to one skilled in the art that the present invention may be practiced without these specific details. In other instances, well-known structures and devices are shown in block diagram form, rather than in detail, in order to avoid obscuring the present invention.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Embodiments of the invention provide a mechanism for concurrent testing of multiple embedded arrays using sharable resources in a cost-effective manner. Embodiments of the invention lead to reduction in both area and power required by design for test (DFT) hardware and reduction in test time and overall test cost. These reductions may be significant in newer generations of microprocessors that employ a large number of embedded arrays. For example, some microprocessors may have over a few hundred small arrays in their cores and uncores in the form of register files, FIFOs, and CAM arrays. Embodiments of the invention also extend the life of DFT hardware by making it usable for hardware power-on or on-demand self-test in field.

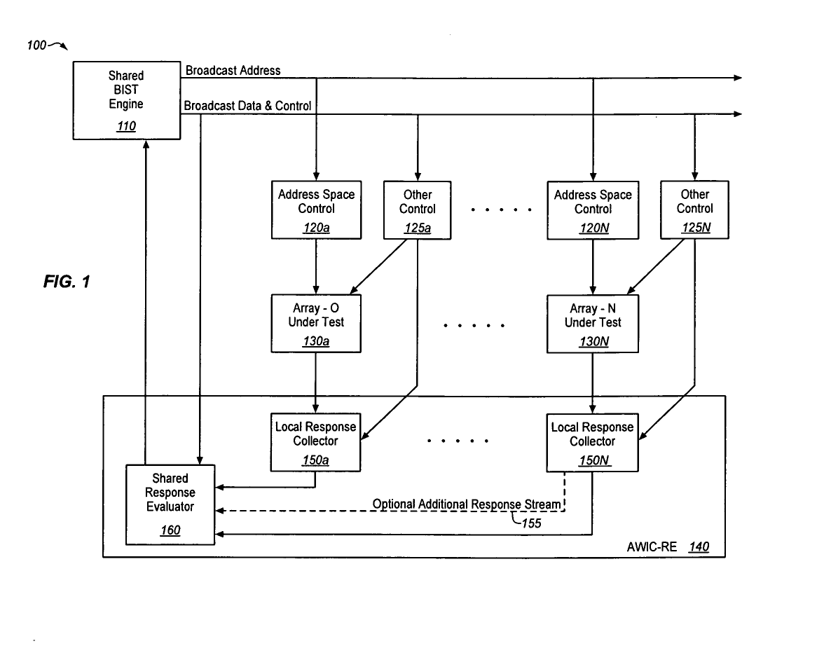

FIG. 1 is a block diagram of one embodiment of a concurrent array test system 100. The key components are the shared BIST engine 110, local address space control logic 120a-120N, other control logic 125a-125N, target arrays under test (Array-0 through Array-N) 130a-130N, and an Array Width-Independent Response Evaluator (AWIC-RE) 140. The AWIC-RE 140 further includes response collectors 150a-150N associated with each array under test 130a-130N and a shared response evaluator 160.

In one embodiment, the shared BIST engine 110 may a hard-wired algorithm engine capable of applying a limited number of array test algorithms. In other embodiment, the shared BIST engine 110 may be a programmable BIST engine capable of applying any kitchen-sink test algorithm. In either case, the shared BIST engine 110 generates test stimuli packets including array address, data, and control signals, and broadcasts these signals over a set of wires to all of the arrays under test 130a-130N.

The arrays under test 130a-130N may be a group of “like-kind” arrays in a processor. These like-kind arrays may have different size and width (number of entries and number of bits per entry) but are otherwise identical in nature so that they may be tested concurrently. For example, all 1 Read/1 Write port arrays may form a “like-kind” array group in some embodiments of the invention. Similarly, all CAM arrays of various sizes may form one “like-kind” array group. Furthermore, in embodiments of the invention, the “like-kind” arrays are tested in parallel; however, embodiments of the invention also envision that the “like-kind” arrays may be tested one at a time, or in a sequential manner.

It is important to note that the shared BIST engine 110 generates these stimuli packets to target the largest array in the system. Each target array receives these stimuli packets in the usual manner of the state-of-the-art, except that in embodiments of the invention, the address is additionally routed through address space control logic 120a-120N located at each array 130a-130N.

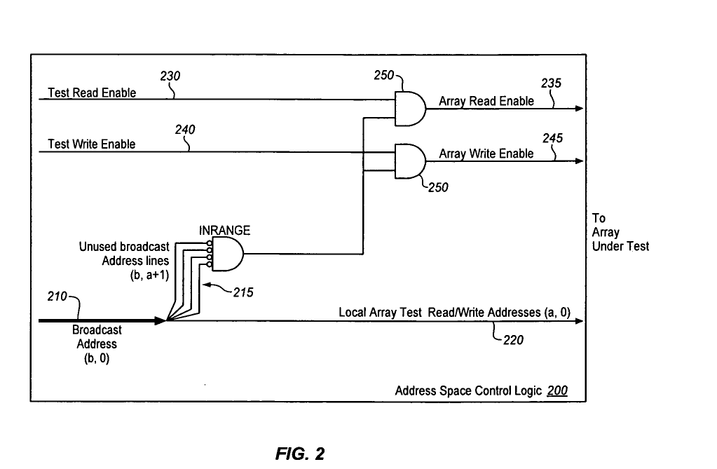

One embodiment of the address space control logic 120a-120N is further depicted in the block diagram of FIG. 2. In one embodiment, address space control logic 200 prunes the broadcast addresses to match the address space of its associated local array. In other words, the address space control logic 200 blocks 215 the reads from and writes to addresses outside the range of addresses implemented in the array. Thus, while the BIST engine may continue to test a target array with larger address space, the address space control 200 maintains the integrity of test algorithm applied at the smaller arrays once the broadcast addresses fall outside their address range.

As shown in FIG. 2, the address space control logic 200 receives the test read enable 230, test write enable 240, and broadcast address 210 signals from the BIST engine. These signals are pruned by gates 215 and 250 to match the address space of the address space control logic's associated array under test. The associated array under test then receives from the address space control logic the pruned array read enable 235, array write enable 245, and local array test read/write addresses 220.

It should be noted that with embodiments of the invention, any non-binary (or 2ⁿ) address space is inherently accommodated. For example, for an array with “a” address bits and address space less than 2^{a}, the out-of-range address writes do not affect array content and the out-of-range address reads obtain the pre-charged read bit lines, which is a deterministic value.

Referring back to FIG. 1, every time an array under test 130a-130N performs a read operation, its read-out response is collected in the AWIC-RE 140. In one embodiment, the AWIC-RE 140 consists of two components: (1) Array Response Collectors 150a-150N located in each target array's read datapath; and (2) a common shared response evaluator 160.

In one embodiment, the response collectors 150a-150N are array read registers that capture data read from the target arrays 130a-130N and serially shift this data into the shared response evaluator 160 under the control 125a-125N of the shared BIST engine 110. In some embodiments, to reduce test hardware cost, any existing read registers may be shared as the response collectors 150a-150N.

During testing and after each read operation, the captured response in each response collector 150a-150N is serially emptied into the response evaluator. The shared BIST engine 110 issues a shift control to empty the widest array (the array with the most bits per entry). As the response collectors 150a-150N empty out read bits from one end, they are filled with zeroes from the other end. Response collectors 150a-150N with fewer bits per entry than the widest array may continue to shift extra cycles with no consequence. This is what makes the response evaluation of embodiments of the invention array-width independent and makes concurrent testing feasible.

In one embodiment, the shared response evaluator 160 is a multiple input signature register (MISR). The shared response evaluator 160 as a MISR compresses the serial response streams returned by response collectors 150a-150N after each read. When the entire test is completed, the final content in the response evaluator MISR 160 are compared with the expected signature. Then, a pass/fail status bit may be set according to the comparison to indicate the test results. In some embodiments, the central BIST engine 110 may perform this comparison and status bit setting. In other embodiments, the shared response evaluator 160 may perform the comparison.

In some embodiments, the expected response signature may be obtained by any number of suitable known techniques, including pre-simulation of the actual BIST test pattern run prior to testing. This pre-simulation will accurately account for all of the read responses and the zero-fills from the smaller-width arrays. In some embodiments, the MISR size may be set to minimize the aliasing probability, or set to the number of serial response streams returned from response collectors 150a-150N, whichever is greater.

As the response collectors 150a-150N serially send data to the response evaluator 160, the BIST engine 110 may pause algorithm execution after every read that the test algorithm observes. At first glance, the serial response compression in the AWIC-RE 140 may appear to increase test time. However, test time is not increased as much because the shifting is done at full internal clock rate. Furthermore, the bandwidth is not hampered by the tester speed or the protocol overheads as is the case in the prior art DAT and LDAT methods.

In fact, some embodiments of the invention may reduce test time. These embodiments may utilize one or more additional taps 155 evenly spaced in the response collectors 150a-150N to return serial responses to the response evaluator 160. The number of shift cycles is thereby reduced by the number of taps taken, which in turn may reduce the overall test time.

In another embodiment of the invention, the response collectors 150a-150N may also be implemented as MISRs, similar to the response evaluator 160. During testing, for every read operation, the response collector MISRs 150a-150N compress their associated array's read responses in parallel and send their serial output (referred to as Quotient bit or Q-bit) to the response evaluator MISR 160 for a second level compression. At the end of the test, the response evaluator MISR 160 signature is compared to the expected signature to obtain the collective pass/fail status for the array group. In addition, the response collector MISRs 150a-150N signatures are each individually compared the expected signature for each response collector to obtain the pass/fail status of the individual arrays in the group. In some embodiments, the comparison of the response collector MISR 150a-150N signatures is performed by the central BIST engine 110.

In this embodiment, because the responses are compressed in parallel, the shared BIST engine 110 may stream the test stimuli packets at full speed without any pauses. This significantly reduces the test time. Furthermore, the second level MISR in the response evaluator 160 gives additional protection against aliasing. This is valuable for arrays with a small number of bits per entry. This embodiment may have to utilize additional circuits to implement the response collectors 150a-150N as MISRs.

In other embodiments of the invention, the MISRs in the AWIC-RE 140 may be replaced with actual comparators. For example, the MISR in the shared response evaluator 160 may be replaced by bit-wise serial comparators, one for each returning response stream. However, as typical data used for testing arrays includes replicated fields of a fixed-width data pattern, this embodiment may involve additional effort in two areas to make the response evaluation width-independent. First, the serial comparator should utilize dummy bits to make the total width returned from the response collector 150a-150N appear as an integer multiple of the width of the replicated data pattern. Second, the narrower response collectors 150a-150N should recirculate the responses, rather than zero-fill them.

Similarly, if MISRs are utilized in the response collectors 150a-150N of the AWIC-RE 140, these MISRs may be replaced directly with parallel comparators. The expected response data in this case is derived from the test stimuli packet broadcast from the BIST engine 110. The compare result may then be captured in a sticky pass/fail status bit for each array under test 130a-130N. The shared response evaluator 160 then merges into additional small circuitry in the response collectors 150a-150N. In addition, both of the actual comparator implementation schemes described above may utilize more complex address space control logic 120a-120N when the address space is not binary (2ⁿ).

In other embodiments of the invention, the response collectors 150a-150N may shift out their test content directly to an off-chip test system outside of the microprocessor. This test system may be a computer or other processing component, including autometic test equipment. The test contents that are directly shifted out may then be utilized for further detailed analysis, fault analysis, debugging purposes, and/or diagnosis purposes.

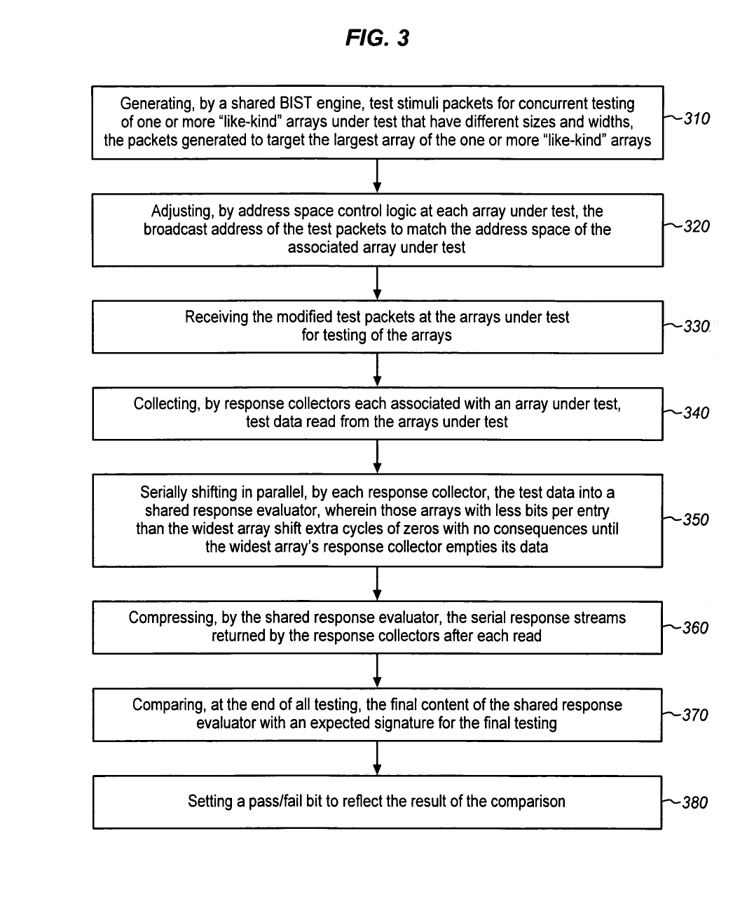

FIG. 3 is a flow diagram of a method according to one embodiment of the invention. Process 300 is a method for concurrent testing of multiple embedded arrays in a processor. In one embodiment, process 300 may be performed by the components described with respect to FIG. 1. For the purposes of the following discussion, assume that the response collectors are implemented as read registers and the response evaluator is implemented as an MISR. One skilled in the art will appreciated that other implementations, such as the embodiment described above implementing the response collectors as MISRs, are also envisioned.

Process 300 begins at processing block 310 where a shared BIST engine generates test stimuli packets for concurrent testing of one or more “like-kind” arrays under test that may have different sizes and widths. The test stimuli packets are generated to target the largest array of the one or more like-kind arrays under test. Then, at processing block 320, address space control logic at each array under test adjusts the broadcast address of the test packets to match the address space of its array under test. At processing block 330, the modified test packets are received at the arrays for testing of the arrays.

Then, at processing block 340, response collectors associated with each array under test collect test data read from the arrays under test. Each response collector serially shifts in parallel the test data into a shared response evaluator at processing block 350. Those arrays with fewer bits per entry that the widest array shift extra cycles of zeroes with no consequences until the widest array's response collector empties its data.

Then, at processing block 360, the shared response evaluator compresses the serial response streams returned by the response collectors after each read. At processing block 370, at the end of all testing, the final content of the shared response evaluator is compared with an expected signature for the final testing. In some embodiments this comparison may be performed by the BIST engine. In other embodiments, the comparison may be performed by the shared response evaluator. In yet other embodiments, the comparison may be performed by an off-chip test system.

Finally, at processing block 380, a pass/fail bit is set to reflect the result of the comparison. For instance, if the contents of the shared response evaluator do not match the expected results, then the pass/fail bit is set to indicate a fail. If the contents to match the expected results, then the pass/fail bit is set to indicate a pass. In some embodiments, the component that performs the comparison on processing block 370 may also set the pass/fail bit.

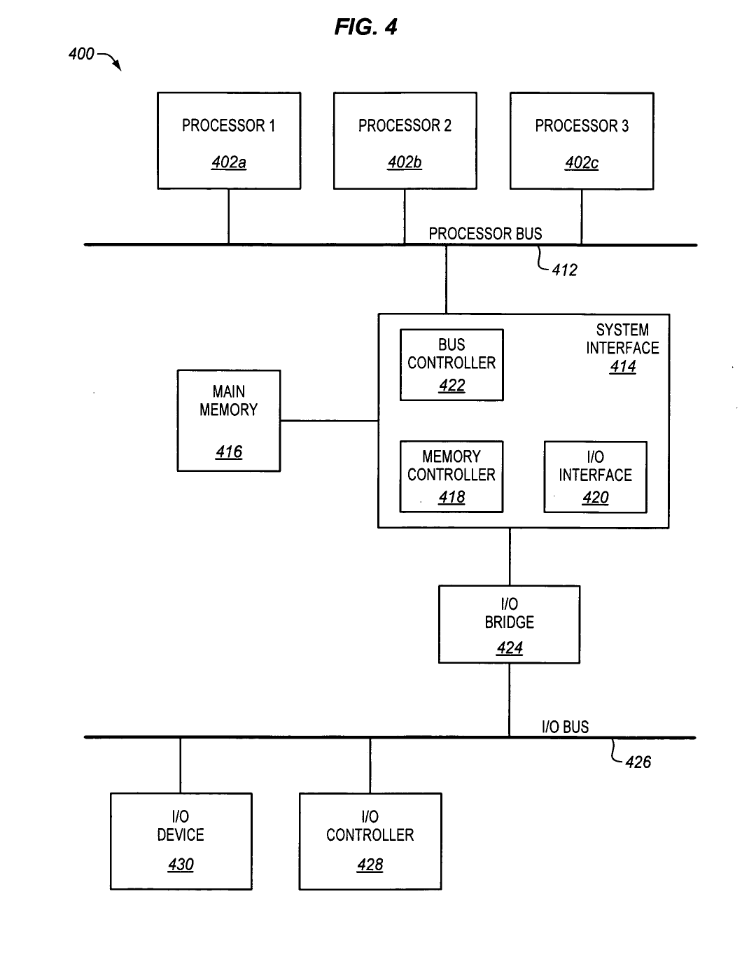

FIG. 4 is a block diagram illustrating an exemplary computer system (system) 400 used in implementing one or more embodiments of the invention. Components of FIGS. 1 through 3 may be implemented as system 400 or as components of system 400. System 400 includes one or more processors 402a-c. The processors 402a-c may include one or more single-threaded or multi-threaded processors. A typical multi-threaded processor may include multiple threads or logical processors, and may be capable of processing multiple instruction sequences concurrently using its multiple threads.

Processors 402a-c may also include one or more internal levels of cache and a bus controller or bus interface unit to direct interaction with the processor bus 412. As in the case of chip multiprocessors or multi-core processors, processors 402a-c may be on the same chip. The chip may include shared caches, interprocessor connection networks, and special hardware support such as those for SPT execution (not shown). Furthermore, processors 402a-c may include multiple processor cores. Processor bus 412, also known as the host bus or the front side bus, may be used to couple the processors 402a-c with the system interface 414.

System interface 414 (or chipset) may be connected to the processor bus 412 to interface other components of the system 400 with the processor bus 412. For example, system interface 414 may include a memory controller 418 for interfacing a main memory 416 with the processor bus 412. The main memory 416 typically includes one or more memory cards and a control circuit (not shown). System interface 414 may also include an input/output (I/O) interface 420 to interface one or more I/O bridges or I/O devices with the processor bus 412. For example, as illustrated, the I/O interface 420 may interface an I/O bridge 424 with the processor bus 412. I/O bridge 424 may operate as a bus bridge to interface between the system interface 414 and an I/O bus 426. One or more I/O controllers and/or I/O devices may be connected with the I/O bus 426, such as I/O controller 428 and I/O device 430, as illustrated. I/O bus 426 may include a peripheral component interconnect (PCI) bus or other type of I/O bus.

System 400 may include a dynamic storage device, referred to as main memory 416, or a random access memory (RAM) or other devices coupled to the processor bus 412 for storing information and instructions to be executed by the processors 402a-c. Main memory 416 may also be used for storing temporary variables or other intermediate information during execution of instructions by the processors 402a-c. System 400 may include a read only memory (ROM) and/or other static storage device coupled to the processor bus 412 for storing static information and instructions for the processors 402a-c.

Main memory 416 or dynamic storage device may include a magnetic disk or an optical disc for storing information and instructions. I/O device 430 may include a display device (not shown), such as a cathode ray tube (CRT) or liquid crystal display (LCD), for displaying information to an end user. I/O device 430 may also include an input device (not shown), such as an alphanumeric input device, including alphanumeric and other keys for communicating information and/or command selections to the processors 402a-c. Another type of user input device includes cursor control, such as a mouse, a trackball, or cursor direction keys for communicating direction information and command selections to the processors 402a-c and for controlling cursor movement on the display device.

System 400 may also include a communication device (not shown), such as a modem, a network interface card, or other well-known interface devices, such as those used for coupling to Ethernet, token ring, or other types of physical attachment for purposes of providing a communication link to support a local or wide area network, for example. Stated differently, the system 400 may be coupled with a number of clients and/or servers via a conventional network infrastructure, such as a company's intranet and/or the Internet, for example.

It is appreciated that a lesser or more equipped system than the example described above may be desirable for certain implementations. Therefore, the configuration of system 400 may vary from implementation to implementation depending upon numerous factors, such as price constraints, performance requirements, technological improvements, and/or other circumstances.

It should be noted that, while the embodiments described herein may be performed under the control of a programmed processor, such as processors 402a-c, in alternative embodiments, the embodiments may be fully or partially implemented by any programmable or hard coded logic, such as field programmable gate arrays (FPGAs), transistor logic (TTL) logic, or application specific integrated circuits (ASICs). Additionally, the embodiments of the invention may be performed by any combination of programmed general-purpose computer components and/or custom hardware components. Therefore, nothing disclosed herein should be construed as limiting the various embodiments of the invention to a particular embodiment wherein the recited embodiments may be performed by a specific combination of hardware components.

In the above description, numerous specific details such as logic implementations, opcodes, resource partitioning, resource sharing, and resource duplication implementations, types and interrelationships of system components, and logic partitioning/integration choices may be set forth in order to provide a more thorough understanding of various embodiments of the invention. It will be appreciated, however, to one skilled in the art that the embodiments of the invention may be practiced without such specific details, based on the disclosure provided. In other instances, control structures, gate level circuits and full software instruction sequences have not been shown in detail in order not to obscure the invention. Those of ordinary skill in the art, with the included descriptions, will be able to implement appropriate functionality without undue experimentation.

The various embodiments of the invention set forth above may be performed by hardware components or may be embodied in machine-executable instructions, which may be used to cause a general-purpose or special-purpose processor or a machine or logic circuits programmed with the instructions to perform the various embodiments. Alternatively, the various embodiments may be performed by a combination of hardware and software.

Various embodiments of the invention may be provided as a computer program product, which may include a machine-readable medium having stored thereon instructions, which may be used to program a computer (or other electronic devices) to perform a process according to various embodiments of the invention. The machine-readable medium may include, but is not limited to, floppy diskette, optical disk, compact disk-read-only memory (CD-ROM), magneto-optical disk, read-only memory (ROM) random access memory (RAM), erasable programmable read-only memory (EPROM), electrically erasable programmable read-only memory (EEPROM), magnetic or optical card, flash memory, or another type of media/machine-readable medium suitable for storing electronic instructions. Moreover, various embodiments of the invention may also be downloaded as a computer program product, wherein the program may be transferred from a remote computer to a requesting computer by way of data signals embodied in a carrier wave or other propagation medium via a communication link (e.g., a modem or network connection).

Similarly, it should be appreciated that in the foregoing description, various features of the invention are sometimes grouped together in a single embodiment, figure, or description thereof for the purpose of streamlining the disclosure aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Whereas many alterations and modifications of the present invention will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the invention.

What is claimed is:

1. An apparatus, comprising:
a built-in self test (BIST) engine coupled to a plurality of arrays having different sizes to generate test packets targeted to an array with the most entries among the plurality of arrays;
a plurality of address space control logic each associated with an array of the plurality of arrays, the address space control logic to adjust a broadcast address of the test packets to match an address space of its associated array; and
an array width independent concurrent response evaluator (AWIC-RE) coupled to the plurality of arrays including:
a plurality of response collectors each associated with an array of the plurality of arrays, the response collector to collect test data from its associated array and serially shift the test data out; and
a response evaluator to receive the test data response streams from the plurality of response collectors and to compress the serial response streams after each read.

2. The apparatus of claim 1, wherein the BIST engine further to:
compare a final compressed result from the response evaluator with an expected result for testing of the arrays; and
set a pass/fail bit to reflect a result of the comparison.

3. The apparatus of claim 1, wherein the response collectors are implemented as read registers.

4. The apparatus of claim 1, wherein the response evaluator is implemented as a multiple input signature register (MISR).

5. The apparatus of claim 4, wherein the response collectors are implemented as multiple input signature registers (MISRs) to compress the collected test data received their associated arrays.

6. The apparatus of claim 5, wherein the BIST engine further to compare the compressed results from the response collectors with expected results for each response collector to determine if an error occurred in an individual response collector.

7. The apparatus of claim 1, wherein the expected results for the final testing are generated prior to the generation of the test stimuli packets through a simulation.

8. The apparatus of claim 1, wherein the response evaluator is implemented as an actual comparator.

9. The apparatus of claim 1, wherein the response collector serially shifting out the read data further includes shifting extra cycles of zeroes in the response collectors associated with arrays with less bits per entry than the array with the most entries until the response collector associated with the widest array completes shifting out its data.

10. The apparatus of claim 1, wherein the response collectors include one or more additional taps to serially shift out additional test data in parallel.

11. A system, comprising:
a processor coupled to memory and including a plurality of arrays having different sizes and widths; and
a testing interface coupled to the processor to access a concurrent array testing system including:
a built-in self test (BIST) engine coupled to the plurality of arrays to generate test packets targeted to an array with the most entries among the plurality of arrays;
a plurality of address space control logic each associated with an array of the plurality of arrays, the address space control logic to adjust a broadcast address of the test packets to match an address space of its associated array; and
an array width independent concurrent response evaluator (AWIC-RE) coupled to the plurality of arrays including:
a plurality of response collectors each associated with an array of the plurality of arrays, the response collector to collect test data from its associated array and serially shift the test data out; and
a response evaluator to receive the test data response streams from the plurality of response collectors and to compress the serial response streams after each read, and compare a final compressed result with an expected result for testing of the arrays.

12. The system of claim 11, wherein the arrays under test include at least one of random access memory (RAM), content addressable memory (CAM), register files, and first-in-first-out (FIFO) queues.

13. The system of claim 11, wherein the response collector serially shifting out the read data further includes shifting extra cycles of zeroes in the response collectors associated with arrays with less bits per entry than the widest array until the response collector associated with the widest array completes shifting out its data.

14. The system of claim 11, wherein the response evaluator is implemented as a multiple input signature register (MISR).

15. The system of claim 14, wherein the response collectors are implemented as multiple input signature registers (MISRs) to compress the collected test data received their associated arrays, and wherein the BIST engine to compare the compressed results of the response collectors with expected results for each response collector to determine if an error occurred in an individual response collector.

16. A method, comprising:
generating, by a built-in self-test (BIST) engine, test packets for concurrent testing of like-kind arrays under test having different sizes and widths, the test packets to target an array with the most entries among the like-kind arrays;
adjusting, by address space control logic at each array under test, a broadcast address of the test packets to match the address space of the associated array under test;
collecting, by response collectors each associated with an array under test, test data read from the arrays under test;
serially shifting in parallel, by each response collector, the test data into a response evaluator, wherein the arrays with fewer bits per entry than the array with the most entries shift extra cycles of zeroes until the widest array's response collector empties its test data;
compressing, by the response evaluator, the serial response streams of test data after each read;
comparing, by the BIST engine at the end of all testing, the final content of the response evaluator with an expected signature for the final testing.

17. The method of claim 16, further comprising setting, by the BIST engine, a pass/fail bit to reflect the result of the comparison.

18. The method of claim 16, wherein the response collectors and the response evaluator are implemented as multiple input signature registers (MISRs).

19. The method of claim 18, further comprising:
compressing, by the response collectors, the test data into a signature; and
comparing, by the BIST engine, the signature with an expected signature for the response collectors to determine whether an individual array produces an error condition.

20. The method of claim 16, wherein the response evaluator is implemented as an actual comparator.
